(19) United States
(12) Patent Application Publication
(10) Pub. No.: US 2009/0035105 A1
(43) Pub. Date: Feb. 5, 2009

(54) Apparatus for separating chip, a method for fabricating the apparatus, and a method for separating a chip

(75) Inventors: Cheal-Sang Yoon, Cheonan-si (KR); Yong-Dae Ha, Asan-si (KR); Jae-Ryoung Lee, Asan-si (KR); Jeong-Soon Cho, Cheonan-si (KR); Bum-Woo Lee, Asan-si (KR); Young-Gon Hwang, Cheonan-si (KR); Mok-Kun Kwon, Asan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/219,666

(22) Filed: Jul. 25, 2008

(30) Foreign Application Priority Data
Jul. 31, 2007 (KR) 10-2007-0076960

(51) Int. Cl. H01L 21/67

(52) U.S. Cl. 414/225.01; 414/806; 414/787

(57) ABSTRACT

Provided are an apparatus, method for separating a chip and a method for fabricating the apparatus. An apparatus for separating a chip, according to example embodiments, may include a suction holder. The suction holder may include an upper surface with at least one suction hole to suction and fix an adhesive tape to which a plurality of semiconductor chips may be attached. The apparatus for separating a chip may also include a rotatable plunger in the suction holder. The rotatable plunger may include an upper end configured to pass through the at least one suction hole and to project over the suction holder upon rotation of the rotatable plunger. The apparatus for separating a chip may also include a vertically movable plunger lifter. The vertically movable plunger lifter may be configured to rotate the rotatable plunger by contacting and raising a lower end of the rotatable plunger.

### PRIORITY STATEMENT

This application claims priority under 35 U.S.C. §119 to Korean Patent Application No. 2007-0076960, filed on Jul. 31, 2007, in the Korean Intellectual Property Office (KIPO), the entire contents of which are herein incorporated by reference.

### BACKGROUND

1. Field

Example embodiments relate to an apparatus and method for separating a chip, and more particularly, to a chip separation apparatus and method used to separate a semiconductor chip from a semiconductor wafer supported by an attached adhesive tape. Example embodiments also provide for a method of fabricating an apparatus for separating a chip.

2. Description of the Related Art

A semiconductor manufacturing method may include a fabrication (FAB) process to form a plurality of semiconductor chips on a wafer, e.g., a silicon wafer, an electrical die sorting (EDS) process to electrically inspect the plurality of semiconductor chips formed on the wafer and to sort desirable chips from undesirable chips, an assembly process to individually separate the desirable chips from the undesirable chips and to pack each desirable chip so that the desirable chip may maintain its electrical and physical characteristics, and a test process to test the packaged products.

Among the semiconductor manufacturing processes, the assembly process, also known as a package process, may include a wafer sawing process to cut a wafer into individual chips, a die bonding process to select and mount only desirable semiconductor chips on a lead frame or a substrate, a wire bonding process to electrically connect the mounted semiconductor chips to leads of the lead frame, a molding process to seal the semiconductor chip and parts electrically connected thereto using a molding compound, and a form process to form an outer lead in a predetermined or given form appropriate for its mounting type.

The wafer, in which a plurality of semiconductor chips may be formed through the FAB process, may be attached to an adhesive tape on a rear surface thereof. The rear surface may be opposite to the surface on which an integrated circuit may be formed. The adhesive tape may prevent or retard the plurality of semiconductor chips from separating after the wafer is cut during the sawing process. The wafer, to which the adhesive tape may be attached, may be subjected to the die bonding process after the wafer sawing process. The individual chips may be separated from the wafer through the die bonding process to be mounted on a lead frame or a substrate.

FIG. 1 is a schematic perspective view of a conventional die bonder 90. Referring to FIG. 1, the conventional die bonder 90 may include a pick and place device 91 for conveying a desirable semiconductor chip 83 from a wafer 82 attached to an adhesive tape 87 to an alignment stage 81 using a picker 92. The semiconductor chip 83 may be conveyed from the alignment stage 81, by the pick and place device 91, to a chip attachment region of a substrate 85. An adhesive agent 84 may be applied to bond the semiconductor chip 83 to the substrate 85. The die bonder 90 may also include a bonding head 93 to apply a load for attaching the semiconductor chip 83 to the substrate 85. The die bonder 90 may also include a substrate conveyance device 94 for moving the substrate 85 to an operation position.

In the die bonder 90 having the above configuration, in order to attach the semiconductor chip 83 to the substrate 85 or a lead frame (not shown), an individual semiconductor chip 83 may be separated from the adhesive tape 87, to which the wafer 82 is attached. Therefore, the die bonder 90 may include a chip separation device 100 to separate the individual semiconductor chip 83 from the adhesive tape 87, in addition to the unit devices 91, 93 and 94 for attaching the semiconductor chip 83 to the substrate 85 or the lead frame. Reference numeral 86 designates a wafer fixing ring used to spread the adhesive tape 87, to which the wafer 82 may be attached.

FIG. 2 is an exploded perspective view showing one example of a conventional chip separation device, and FIG. 3 is an operational view of the conventional chip separation device shown in FIG. 2. Referring to FIGS. 2 and 3, the conventional chip separation device 100 may include a suction holder 110 under the wafer 82 to suction and fix the adhesive tape 87, chip lift pins 120 to raise the semiconductor chip 83 from the suctioned and fixed adhesive tape 87, and a pin holder 121 to which the chip lift pins 120 may be fixed.

The suction holder 110 may be a hollow cylinder member, one part of which, for example a lower part, may be open. The suction holder 110 may have pin insertion holes 113 on an upper surface thereof and into which the chip lift pins 120 may be inserted. The suction holder 110 may also have suction holes 111 for suctioning the adhesive tape 87 attached to a lower surface of the wafer 82 using a vacuum, and circular suction grooves 115 for connecting the suction holes 111.

The chip lift pins 120 may be fixed to an upper surface of the pin holder 121 and may be vertically moved through the pin insertion holes 113 by moving the pin holder 121 vertically. The chip lift pins 120 may include four pins to raise a lower surface of the semiconductor chip 83 at four corners thereof to separate the semiconductor chip 83 from the adhesive tape 87.

The pin holder 121 may be coupled to a holder shaft 122 to raise or lower the pin holder 121. The holder pin holder 121 may be guided by the suction holder 110. Accordingly, the chip lift pins 120 may be raised through the pin insertion holes 113 of the suction holder 110 to separate the semiconductor chip 83 from the adhesive tape 87 and to raise a lower surface of the semiconductor chip 83 attached to the adhesive tape 87. The picker (92 of FIG. 1) may pick up the semiconductor chip 83 separated from the adhesive tape 87.

However, in the case of the conventional chip separation device 100, because the semiconductor chip 83 may be separated from the adhesive tape 87 in such a manner that the plurality of chip lift pins 120 may be directly and vertically moved from just under the semiconductor chip 84, which is to be separated, excessive stress may be applied to the separated semiconductor chip 83, and therefore, the semiconductor chip 83 may be readily broken or cracked. In particular, the bond between a semiconductor chip 83 and an adhesive tape may be relatively strong after the semiconductor chip 83 and adhesive have been attached for a relatively long time. Therefore, the likelihood of breaking a semiconductor chip 83 with a conventional chip separation apparatus may increase for a semiconductor chip 83 attached to an adhesive tape for a relatively long time.

### SUMMARY

Example embodiments provide an apparatus and method for separating a chip capable of reducing stress applied to a semiconductor chip when the semiconductor chip is separated from an adhesive tape. Example embodiments also provide for a method fabricating an apparatus for separating a chip.

An apparatus for separating a chip, according to example embodiments, may include a suction holder. The suction holder may include an upper surface with at least one suction hole to suction and fix an adhesive tape to which a plurality of semiconductor chips may be attached. The apparatus for separating a chip, according to example embodiments, may also include a rotatable plunger in the suction holder. The rotatable plunger may include an upper end configured to pass through the at least one suction hole and to project over the suction holder upon rotation of the rotatable plunger. The apparatus for separating a chip, according to example embodiments, may also include a vertically movable plunger lifter at a lower part of the suction holder. The vertically movable plunger lifter may be configured to rotate the rotatable plunger by contacting and raising a lower end of the rotatable plunger.

A method of separating a chip, according to example embodiments, may include positioning a suction holder at a lower part of an adhesive tape to which a plurality of semiconductor chips are attached. The suction holder may include at least an upper surface with at least one suction hole. The method of separating a chip, according to example embodiments, may also include providing vacuum suction through the suction hole and fixing the adhesive tape to the upper surface of the suction holder. The method of separating a chip, according to example embodiments, may also include raising a plunger lifter at a lower part of the suction holder to rotate the plunger such that the semiconductor chip may be separated from the adhesive tape, as the plunger rotatably installed in the suction holder is rotated to project over the suction holder on its upper end.

A method of fabricating an apparatus for separating a chip, according to example embodiments, may include forming a suction holder including an upper surface with at least one suction hole to suction and fix an adhesive tape to which a plurality of semiconductor chips may be attached. A method of fabricating an apparatus for separating a chip, according to example embodiments, may also include mounting a rotatable plunger in the suction holder. The rotatable plunger may include an upper end configured to pass through the at least one suction hole and to project over the suction holder upon rotation of the rotatable plunger. A method of fabricating an apparatus for separating a chip, according to example embodiments, may also include providing a vertically movable plunger lifter on a lower part of the suction holder configured to rotate the rotatable plunger by contacting and raising a lower end of the rotatable plunger.

### BRIEF DESCRIPTION OF THE DRAWINGS

Example embodiments will be more clearly understood from the following detailed description taken in conjunction with the accompanying drawings. FIGS. 1-3 represent perspective and operation views of a conventional die bonder. FIGS. 4-9 represent non-limiting, example embodiments as described herein.

FIG. 1 is a schematic perspective view of a conventional die bonder;

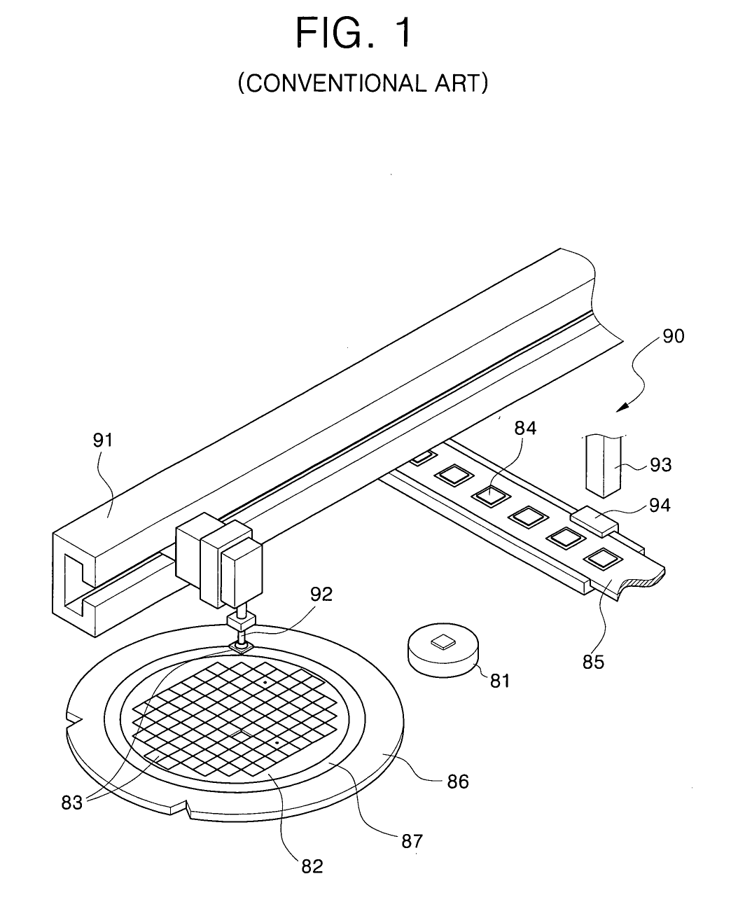

FIG. 2 is an exploded perspective view showing one example of a conventional chip separation device;

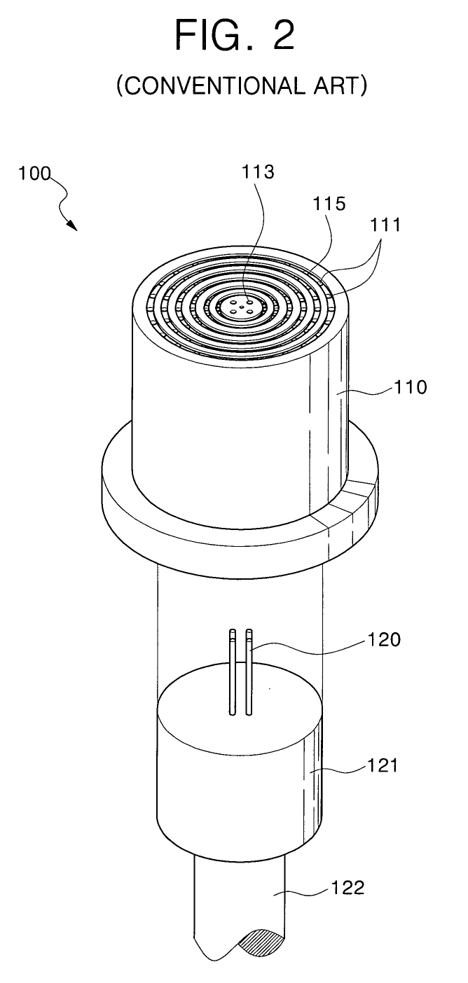

FIG. 3 is an operational view of the conventional chip separation device shown in FIG. 2;

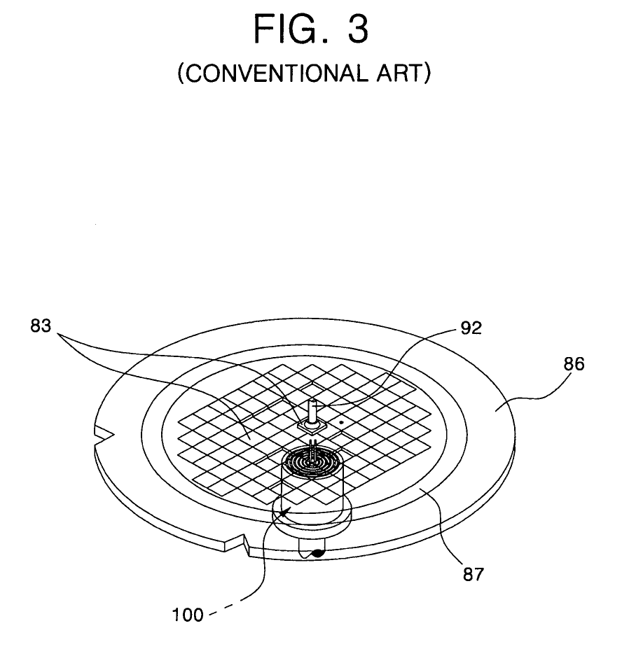

FIG. 4 is a perspective view of an apparatus for separating a chip in accordance with example embodiments;

FIG. 5 is a perspective view illustrating the internal configuration of the chip separation apparatus shown in FIG. 4;

FIG. 6 is a perspective view illustrating an operation state of the chip separation apparatus shown in FIG. 4;

FIGS. 7A and 7B are cross-sectional views taken along line I-I′ of the chip separation apparatus shown in FIG. 4, wherein FIG. 7A shows a state before operation of the chip separation apparatus and FIG. 7B shows an operation state of the chip separation apparatus;

FIGS. 8A and 8B are cross-sectional views taken along line II-II′ of the chip separation apparatus shown in FIG. 4, wherein FIG. 8A shows a state before operation of the chip separation apparatus and FIG. 8B shows an operation state of the chip separation apparatus; and

FIG. 9 is a flowchart showing a method of separating a chip in accordance with example embodiments.

### DETAILED DESCRIPTION OF EXAMPLE EMBODIMENTS

Example embodiments will now be described more fully with reference to the accompanying drawings, in which example embodiments are shown. Example embodiments may, however, be embodied in different forms and should not be construed as limited to the embodiments set forth herein. Rather, these embodiments are provided so that this disclosure will be thorough and complete, and will fully convey the scope of example embodiments to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

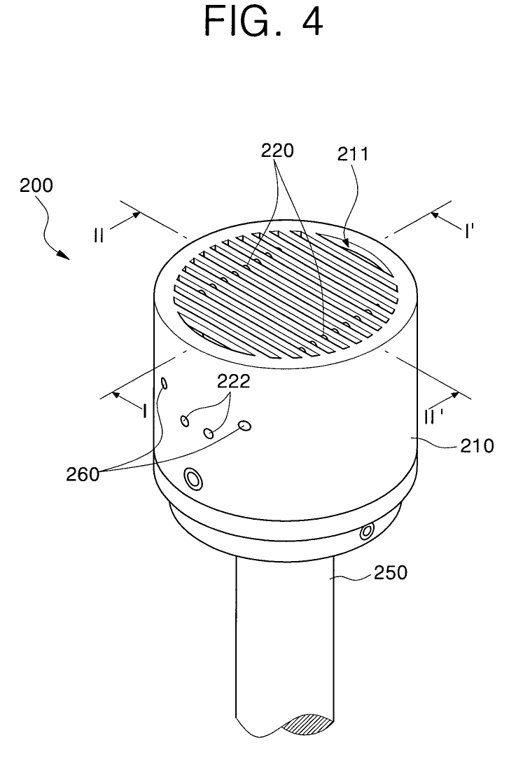

Example embodiments will now be described more fully hereinafter with reference to FIGS. 4 to 9, in which example embodiments are shown. Example embodiments may, however, be embodied in different forms and should not be construed as limited to the embodiments set forth herein. Rather, example embodiments are provided so that this disclosure will be thorough and complete, and will fully convey the scope of example embodiments to those skilled in the art. Like numbers refer to like elements throughout the specification.

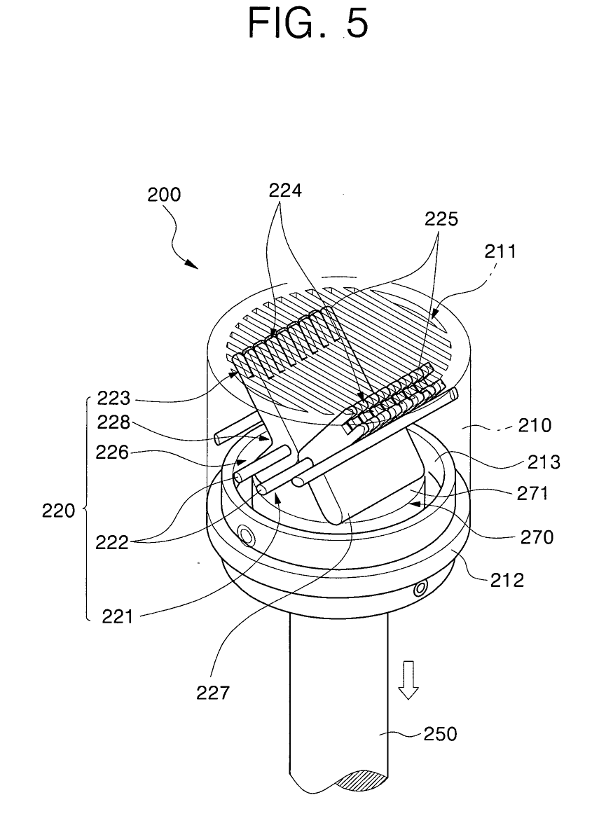

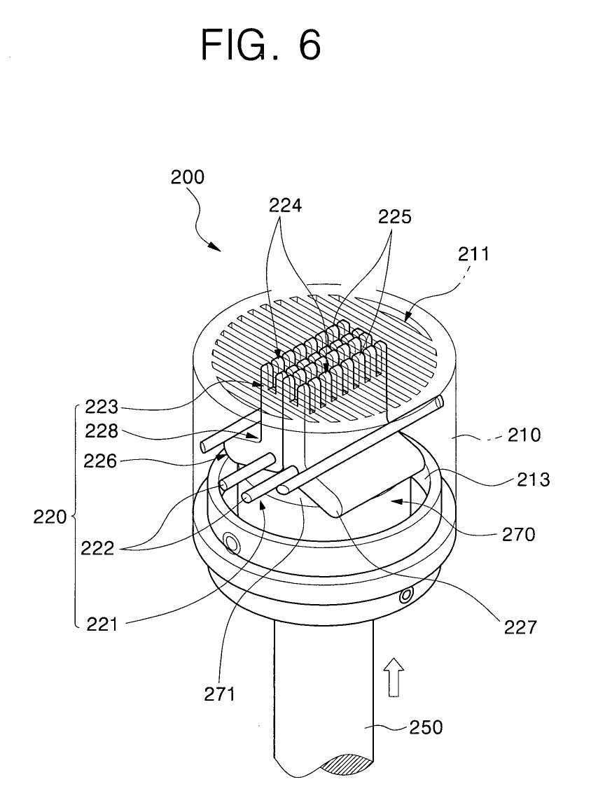

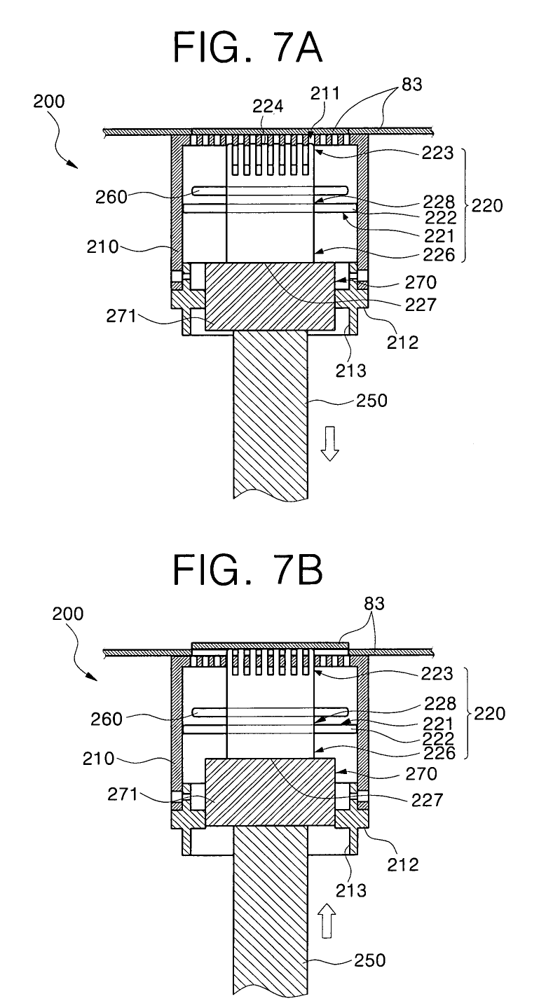

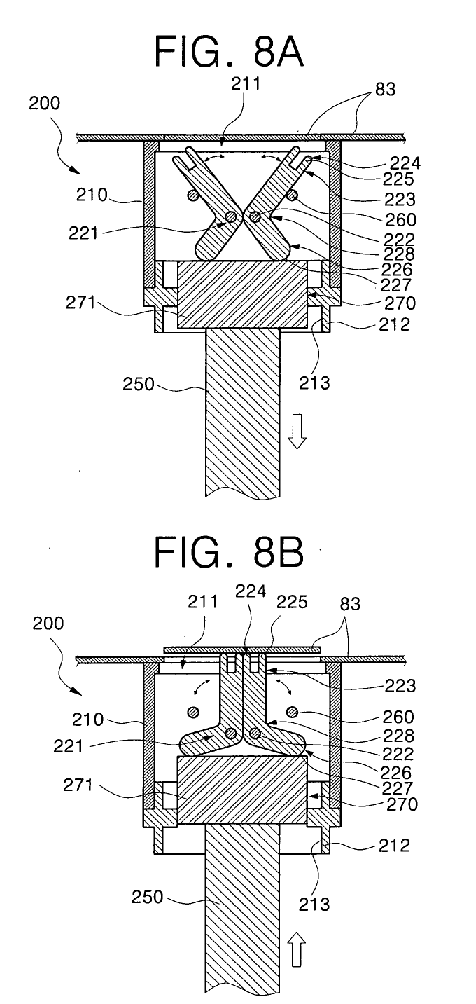

FIG. 4 is a perspective view of an apparatus for separating a chip in accordance with example embodiments, FIG. 5 is a perspective view illustrating the internal configuration of the chip separation apparatus shown in FIG. 4, and FIG. 6 is a perspective view illustrating an operation state of the chip separation apparatus shown in FIG. 4. FIGS. 7A and 7B are cross-sectional views taken along line I-I′ of the chip separation apparatus shown in FIG. 4, wherein FIG. 7A shows a state before operation of the chip separation apparatus and FIG. 7B shows an operation state of the chip separation apparatus. FIGS. 8A and 8B are cross-sectional views taken along line II-II′ of the chip separation apparatus shown in FIG. 4, wherein FIG. 8A shows a state before operation of the chip separation apparatus and FIG. 8B shows an operation state of the chip separation apparatus.

Referring to FIGS. 4 to 8B, a chip separation apparatus 200 in accordance with example embodiments may include a suction holder 210, a plunger 220, a plunger lifter 250, a plunger position recovery device 270, and a plunger rotation stopper 260. The suction holder 210 may have suction holes 211 on its upper surface. The suction holes 211 may fix an adhesive tape 87, to which a plurality of semiconductor chips 83, e.g., semiconductor chips 83 divided from a wafer 82 through cutting, may be attached. The plunger 220 may be installed in the suction holder 210 and may be configured to rotate in the suction holder 210. The plunger lifter 250 may be configured to raise a lower end of the plunger 220 to rotate the plunger 220. The plunger position recovering device 270 may be configured to reversely rotate the plunger 220 upon downward movement of the plunger lifter 250 to restore the plunger to its original position. The plunger rotation stopper 260 may be configured to prevent or reduce reverse rotation of the plunger 220 beyond a preset or given position upon reverse rotation of the plunger 220.

For example, the suction holder 210 may have a substantially hollow cylindrical shape, an upper surface which may be in contact with a lower surface of the adhesive tape 87 during a chip separation operation, and a lower surface which may be open. The upper surface may have a plurality of suction holes 211 at predetermined or given intervals. The suction holder 210 may also have a holder cap 212 with a lifter insertion hole 213 formed at its center. The holder cap 212 may be coupled to the opened lower surface of the suction holder 210. Accordingly, the plunger lifter 250 may be inserted into the suction holder 210 via the lifter insertion hole 213 formed at the holder cap 212 and may be raised or lowered in the suction holder 210.

The upper surface of the suction holder 210 may be in contact with the lower surface of the adhesive tape 87. Vacuum suction, e.g., vacuum pressure, may be applied to the suction holder 210 and may be transmitted to the lower surface of the adhesive tape 87 through the suction holes 211 of the suction holder 210. Therefore, the adhesive tape 87 may be fixed to the upper surface of the suction holder 210 by the vacuum suction transmitted as described above.

The plunger 220 may be rotated in the suction holder 210 and may pass through the suction holes at its upper end and project over the suction holder 210. Therefore, the semiconductor chip(s) 83 attached to the adhesive tape 87 may be separated from the adhesive tape 87 by the upper end of the plunger 220 projecting over the suction holder 210.

The plunger 220 may include a pair of plungers. The pair of plunger may include a first plunger on one side of the suction holder 210, and a second plunger on the other side of the suction holder 210. The plungers 220 may be symmetrically installed with respect to a centerline of the suction holder 210, or may be installed to be rotated in opposite directions when the plunger lifter 250 is moved upward to raise the plungers 220.

The plunger 220 may include a chip lift part 223. The chip lift part may pass through the suction holes 211 and may project over the suction holder 210 upon rotation of the plunger 220. The plunger 220 may also include a lifter contact part 226. The lifter contact part 226 may be in contact with the plunger lifter 250 upon upward movement of the plunger lifter 250. The plunger 220 may also include a bent part 228. The bent part 228 may connect the chip lift part 223 to the lifter contact part 226 to form a certain angle.

The chip lift part 223 may designate an upper part of the plunger 220. A portion of the chip lift part 223 may be configured to project over the suction holder 210 upon rotation of the plunger 220. This portion of the chip lift part 223 may include a plurality of chip lift pins 224. Therefore, when the plunger 220 is rotated, the chip lift pins 224 may project over the suction holder 210 to separate the semiconductor chip 83 from the adhesive tape 87. The chip lift pins 224 may be disposed in two rows as shown in FIG. 5. In example embodiments, separation of the semiconductor chip 83 may be more readily performed.

Because the chip lift pins 224 may project over the suction holder 210 when the plunger 220 is rotated, the chip lift pins 224 may project over the suction holder 210 gradually from one upper side to the other side of the suction holder 210, rather than projecting from any one position of the suction holder 210 as in the conventional art. For example, the chip lift pins 224 may gradually project from an upper periphery toward a center part of the suction holder 210. Therefore, the semiconductor chip 83 attached to the adhesive tape 87 may receive a load applied in a direction inclined at a certain angle along any one path, rather than a load applied in a vertical direction at any one point as in the conventional art. Therefore, the semiconductor chip 83 attached to the adhesive tape 87 may be more smoothly separated from the adhesive tape 87. An upper end of the chip lift part 223, for example, upper ends of the chip lift pins 224, may have curved surfaces 225. In example embodiments, the upper ends of the chip lift pins 224 may more smoothly contact the adhesive tape 87.

The lifter contact part 226 may designate a lower part of the plunger 220, and a lower end of the lifter contact part 226, which may be in contact with the plunger lifter 250, may have a curved surface 227. Therefore, the plunger lifter 250 may more smoothly contact the lifter contact part 226. In example embodiments, a roller (not shown) may be installed on a lower end of the lifter contact part 226. In example embodiments, the plunger lifter 250 may more smoothly contact the lifter contact part 226.

The bent part 228 may connect the chip lift part 223 to the lifter contact part 226 to form a certain angle, for example, about 110°±20°. The plunger lifter 250 may be moved upward and the plunger 220 may be rotated by the bent part 228. The bent angle may be varied to other angles, in addition to about 110°±20°. Hinge parts 221 may be installed on both surfaces of the bent part 228 to rotate the plunger 220. For example, the hinge parts 221 may be a rotation shaft 222 rotatably installed at an inner wall of the suction holder 210. Therefore, the plunger 220 may be rotated about the rotation shaft 222.

The plunger lifter 250 may be installed on a lower part of the suction holder 210 and may be vertically movable. The plunger lifter 250 may be installed to raise the plunger 220 from the lower part of the suction holder 210. Therefore, when rotation of the plunger 220 is needed in order to separate the semiconductor chip 83 from the adhesive tape 87, the plunger lifter 250 may be moved upward to rotate the plunger 220. The plunger 220 may need to be restored to its original position after the semiconductor chip 83 is separated from the adhesive tape 87. The plunger position recovering device 270 may reversely rotate the plunger 220 to restore the plunger 220 to its original or given position when the plunger lifter 250 is moved downward.

In example embodiments, the plunger 220 may be formed of a metal material and the plunger position recovering device 270 may be implemented by a magnet installed at an upper part of the plunger lifter 250. In example embodiments, the plunger position recovering device 270 may be moved downward with the plunger lifter 250 when the plunger lifter 250 is lowered, thereby generating a magnetic pull on the plunger 220. Therefore, the plunger 220 may reversely rotate, by the magnetic force from the plunger position recovering device 270, to return to its original position. The plunger position recovering device 270 is not limited to the above configuration or device. For example, the plunger position recovering device 270 may be implemented by the hinge parts 221 of the plunger 220 and a torsion spring (not shown) installed on the plunger 220 to recover the position of the plunger 220.

The plunger rotation stopper 260 may be provided to prevent or reduce reverse rotation of the plunger 220 beyond a preset or given position upon reverse rotation of the plunger 220, and may be implemented by a stopping pin installed in the suction holder 210. Therefore, when the plunger 220 is reversely rotated by a magnetic force generated from the plunger position recovering device 270, the plunger 220 may be stopped by the stopping pin installed in the suction holder 210. Therefore, the reverse rotation of the plunger 220 may be stopped by the stopping pin, thereby stopping the plunger 220 at the preset or given position.

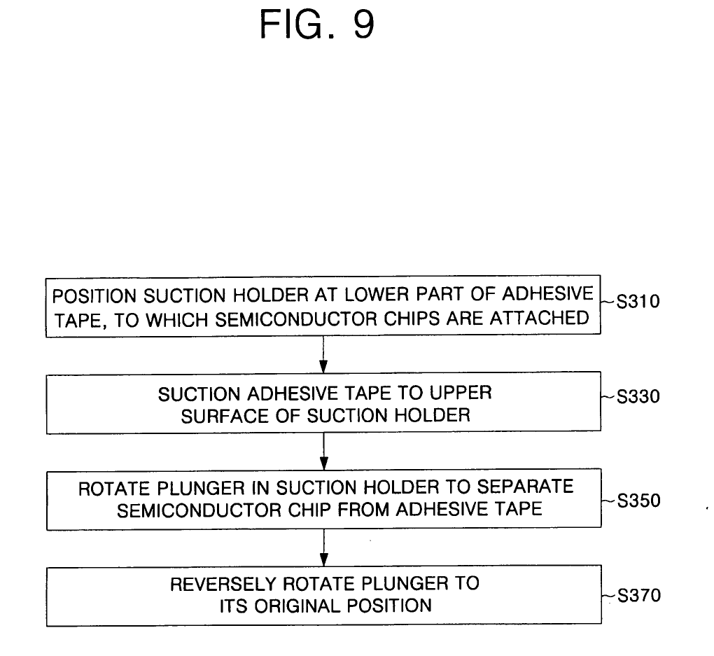

FIG. 9 is a flowchart showing a chip separation method in accordance with example embodiments. As shown in FIG. 9, an adhesive tape 87, to which a plurality of semiconductor chips 83 are attached, may be prepared. A suction holder 210 having suction holes 211 formed on its upper surface may be positioned under the adhesive tape 87, to which the plurality of semiconductor chips 83 may be attached (S310). The suction holder 210 may be disposed under the adhesive tape 87. A vacuum suction may be provided through the suction holes 211 of the suction holder 210 to fix the adhesive tape 87 to the upper surface of the suction holder 210 (S330).

The adhesive tape 87 may be fixed to the upper surface of the suction holder 210. The plunger 220 rotatably installed in the suction holder 210 may be rotated to project its upper end over the suction holder 210. The plunger lifter 250 may be installed on a lower part of the suction holder 210 and may be raised to rotate the plunger 220 to separate the semiconductor chip 83 from the adhesive tape 87. The plunger 220 may be rotated by upward movement of the plunger lifter 250, and rotation of the plunger 220 may project the upper end of the plunger 220 over the suction holder 210. The semiconductor chip 83 attached to the adhesive tape 87 may be separated from the adhesive tape 87 by the upper end of the plunger 220 projecting over the suction holder 210 (S350).

When the semiconductor chip 83 is separated, the plunger lifter 250 may be lowered. Because the plunger position recovering device 270 may be installed on an upper part of the plunger lifter 250, the plunger position recovering device 270 may be lowered together with the plunger lifter 250 upon downward movement of the plunger lifter 250 to generate a magnetic pull on the plunger 220. Therefore, the plunger 220 may reversely rotate by the magnetic pull from the plunger position recovering device 270 to return to its original position (S370). Because the plunger rotation stopper 260 may be installed in the suction holder 210, the plunger 220 may not be reversely rotated beyond the preset or given position upon reverse rotation of the plunger 220 due to the plunger rotation stopper 260.

In accordance with an apparatus and method for separating a chip according to example embodiments, a plunger may be rotated by upward movement of a plunger lifter to project over a suction holder on its upper end such that a semiconductor chip may be separated from an adhesive tape. Therefore, reducing stress applied to the semiconductor chip when the semiconductor chip is separated from the adhesive tape may be possible. In addition, stably and readily separating the semiconductor chip from the adhesive tape may be possible.

While example embodiments have been particularly shown and described with reference to example embodiments thereof, it will be understood by those of ordinary skill in the art that various changes in form and details may be made therein without departing from the spirit and scope of the following claims.

What is claimed is:

1. An apparatus for separating a chip, comprising:
a suction holder including an upper surface with at least one suction hole configured to suction and fix an adhesive tape to which a plurality of semiconductor chips are attached;
a rotatable plunger in the suction holder, the rotatable plunger including an upper end configured to pass through the at least one suction hole and to project over the suction holder upon rotation of the rotatable plunger; and
a vertically movable plunger lifter on a lower part of the suction holder configured to rotate the rotatable plunger by contacting and raising a lower end of the rotatable plunger.

2. The apparatus according to claim 1, further comprising:
a plunger position recovering device configured to reversely rotate the rotatable plunger upon downward movement of the vertically movable plunger lifter to restore the rotatable plunger to its original position.

3. The apparatus according to claim 2, wherein the rotatable plunger includes a metal material, and
the plunger position recovering device is a magnet on an upper part of the vertically movable plunger lifter.

4. The apparatus according to claim 2, further comprising:
a plunger rotation stopper in the suction holder configured to reduce reverse rotation of the rotatable plunger beyond a preset position of the rotatable plunger upon reverse rotation of the rotatable plunger.

5. The apparatus according to claim 1, wherein the rotatable plunger includes a bent part between upper and lower ends of the rotatable plunger.

6. The apparatus according to claim 5, wherein hinge parts are on both sides of the bent part to rotate the rotatable plunger.

7. The apparatus according to claim 1, wherein the rotatable plunger includes a chip lift part configured to pass through the suction hole on one portion and configured to project over the suction holder upon rotation of the rotatable plunger, a lifter contact part in contact with the vertically movable plunger lifter upon upward movement of the vertically movable plunger lifter, and a bent part for connecting the chip lift part to the lifter contact part to form a given angle.

8. The apparatus according to claim 7, wherein a plurality of chip lift pins are on a portion of the chip lift part projecting over the suction holder.

9. The apparatus according to claim 7, wherein an upper end of the chip lift part and a lower end of the lifter contact part are rounded.

10. The apparatus according to claim 1, wherein the rotatable plunger is a pair of rotatable plungers, the pair of rotatable plungers including upper ends configured to pass through the at least one suction hole and to project over the suction holder upon rotation of the pair of rotatable plungers and the vertically movable plunger lifter on a lower part of the suction holder is configured to rotate the pair of rotatable plungers by contacting and raising lower ends of the pair of rotatable plungers.

11. The apparatus according to claim 10, wherein the pair of rotatable plungers are configured to rotate in opposite directions upon upward movement of the vertically movable plunger lifter.

12. The apparatus according to claim 10, further comprising:
a plunger position recovering device for reversely rotating the pair of rotatable plungers upon downward movement of the vertically movable plunger lifter to restore the pair of rotatable plungers to their original position.

13. The apparatus according to claim 12, wherein the pair of rotatable plungers includes a metal material, and the plunger position recovering device is a magnet installed on an upper part of the vertically movable plunger lifter.

14. The apparatus according to claim 12, further comprising:
a pair of plunger rotation stoppers installed at the suction holder to reduce reverse rotation of the pair of rotatable plungers beyond a preset position of the pair of rotatable plungers upon reverse rotation of the pair of rotatable plungers.

15. The apparatus according to claim 10, wherein the pair of rotatable plungers includes bent parts between upper and lower ends of the pair of rotatable plungers.

16. The apparatus according to claim 15, wherein hinge parts are installed at both sides of the bent parts to rotate the pair of rotatable plungers.

17. A method of separating a chip, comprising:
positioning a suction holder on a lower part of an adhesive tape to which a plurality of semiconductor chips are attached, the suction holder including at least an upper surface with at least one suction hole;
providing vacuum suction through the suction hole and fixing the adhesive tape to the upper surface of the suction holder; and
raising a plunger lifter on a lower part of the suction holder to rotate a rotatable plunger such that the semiconductor chip is separated from the adhesive tape, and the rotatable plunger in the suction holder is rotated to project its upper end over the suction holder.

18. The method according to claim 17, further comprising:
lowering the plunger lifter after the semiconductor chip is separated from the adhesive tape to reversely rotate the rotatable plunger to its original position.

19. The method according to claim 18, wherein the rotatable plunger includes a metal material and the upper part of the plunger lifter includes a magnet to reversely rotate the rotatable plunger using a magnetic force.

20. The method according to claim 19, wherein a plunger rotation stopper is in the suction holder to reduce reverse rotation of the plunger beyond a preset position upon reverse rotation of the plunger.

21. A method of fabricating an apparatus for separating a chip, comprising:
forming a suction holder including an upper surface with at least one suction hole configured to suction and fix an adhesive tape to which a plurality of semiconductor chips are attached;
mounting a rotatable plunger in the suction holder, the rotatable plunger including an upper end configured to pass through the at least one suction hole and to project over the suction holder upon rotation of the rotatable plunger; and
providing a vertically movable plunger lifter on a lower part of the suction holder configured to rotate the rotatable plunger by contacting and raising a lower end of the rotatable plunger.
